(19) United States
(12) Patent Application Publication
(10) Pub. No.: US 2014/0180614 A1
(43) Pub. Date: Jun. 26, 2014

(54) System And Method For Selective Estimation Of Battery State With Reference To Persistence Of Excitation And Current Magnitude

(71) Applicants: BOSCH ENERGY STORAGE SOLUTIONS LLC, Farmington Hills, MI (US); ROBERT BOSCH GMBH, Stuttgart (DE)

(72) Inventors: Nalin Chaturvedi, Sunnyvale, CA (US); Michael Schoenleber, Sunnyvale, CA (US); Christopher Mayhew, Union City, CA (US); Reinhardt Klein, Mountain View, CA (US); Jasim Ahmed, Mountain View, CA (US); Aleksandar Kojic, Sunnyvale, CA (US)

(73) Assignees: Robert Bosch GmbH, Stuttgart (DE); Bosch Energy Storage Solutions LLC, Farmington Hills, MI (US)

(21) Appl. No.: 13/727,187

(22) Filed: Dec. 26, 2012

(51) Int. Cl. G01R 31/36

(52) U.S. Cl. CPC G01R 31/3648
USPC 702/63

(57) ABSTRACT

A method of monitoring a battery with a controller identifies appropriate times for estimating a state of the battery. The method includes identifying a persistence of excitation in the battery, identifying a magnitude of an electrical current that is supplied to the battery, and performing a state estimation process for the battery only in response to the identified persistence of excitation exceeding a first predetermined threshold and the identified magnitude of the electrical current exceeding a second predetermined threshold.

### TECHNICAL FIELD

This disclosure relates generally to batteries, and, more particularly, to methods for estimating state of charge and state of health in batteries.

### BACKGROUND

Batteries are used in a wide range of applications to supply an electrical current that drives a load during a discharge process. Primary batteries, which are also referred to as non-rechargeable batteries, are discharged during use and are unable to drive the load after completion of a single discharge. Examples of primary batteries include, but are not limited to, alkaline batteries and silver oxide batteries. Secondary batteries, which are also referred to as rechargeable batteries, also receive electrical current from a charging device to recharge the battery during a charge process. Examples of rechargeable batteries include, but are not limited to, metal-ion, metal-oxygen, lead acid, rechargeable alkaline, flow batteries, and the like. Examples of metal-ion and metal-oxygen batteries include lithium-ion and lithium-oxygen (sometimes referred to as lithium-air) batteries.

Many applications that use either primary or secondary batteries to supply electrical power benefit from an accurate measurement of the state of the battery at various times during operation. For example, existing estimation processes generate estimates of one or more of a state-of-charge (SOC), state-of-function (SOF), and state-of-health (SOH) during operation of the battery. The SOC of the battery refers to the remaining energy capacity in the battery to drive a load. The SOF of the battery refers to the ability of the battery to produce a given level of electrical power. The SOF can be related to the SOC of the battery as the SOC varies over time. The SOH of the battery refers to internal parameters in the battery that describe the useful lifespan of the battery, such as the amount of charge a rechargeable battery can store as the battery performs multiple charge and discharge cycles.

Monitoring systems typically lack the ability to measure the SOC, SOF, and SOH of the battery directly during operation. Instead, the monitoring systems employ various estimation techniques based on externally identifiable parameters of operation for the battery. For example, one or more of the internal voltage (V), current flow (I), and internal temperature (T) of the battery are monitored during operation of the battery. One or more estimation processes generate estimates of the SOC, SOF, and SOH using the measured voltage, current, and temperature parameters.

The estimation processes enable estimation of the SOC, SOF, and SOH in the battery. During operation, however, the battery often experiences a wide range of operating conditions. For example, individual battery cells in a battery pack, which provides power to an electric or hybrid motor vehicle, undergo varying discharge, charge, and idle operations during relatively short time periods as the vehicle accelerates, decelerates, and stops during operation. Further, when the vehicle is parked the battery pack experiences only minimal power draw for extended time periods.

As is known in the art, the estimation processes can generate unreliable estimates during certain operating modes of the battery. Additionally, many estimation processes generate estimates of the current state of the battery using a history of previously estimated states, meaning that even a comparatively small inaccuracy in the estimation process can compound over time to produce a large error between the actual state of the battery and the estimated state. Consequently, the estimation processes are suspended during certain operating modes, such as when the battery is disconnected from a load. Existing techniques for starting and stopping the estimation processes can, however, introduce additional inaccuracies when the state of the battery changes while the estimation process is suspended. These changes during suspension of the estimation process increase the error between the estimated state and actual state of the battery. In light of these limitations, improvements to battery monitoring systems and methods that improve the accuracy of starting and stopping estimation processes for the state of a battery would be beneficial.

### SUMMARY

In one embodiment, a method of monitoring a battery has been developed. The method includes identifying, with a controller, a persistence of excitation in a battery, identifying, with the controller, a magnitude of an electrical current that is supplied to the battery, and performing, with the controller, a state estimation process for the battery only in response to the identified persistence of excitation exceeding a first predetermined threshold and the identified magnitude of the electrical current exceeding a second predetermined threshold.

In another embodiment, a system for monitoring a battery has been developed. The system includes a sensor configured to identify a level of electrical current that is supplied to the battery, and a controller operatively connected to the sensor. The controller is configured to identify a persistence of excitation in a battery, identify an average magnitude of the electrical current that is supplied to the battery with reference to at least one electrical current level identified by the sensor, and perform a state estimation process for the battery only in response to the identified persistence of excitation exceeding a first predetermined threshold and the identified average magnitude of the electrical current exceeding a second predetermined threshold.

### BRIEF DESCRIPTION OF THE DRAWINGS

FIG. 1 is a schematic diagram of a battery monitoring system.

FIG. 2 is a block diagram of a process for enabling and suspending a state estimation process while monitoring a battery.

### DETAILED DESCRIPTION

For the purposes of promoting an understanding of the principles of the embodiments described herein, reference is now be made to the drawings and descriptions in the following written specification. No limitation to the scope of the subject matter is intended by the references. This disclosure also includes any alterations and modifications to the illustrated embodiments and includes further applications of the principles of the described embodiments as would normally occur to one skilled in the art to which this document pertains.

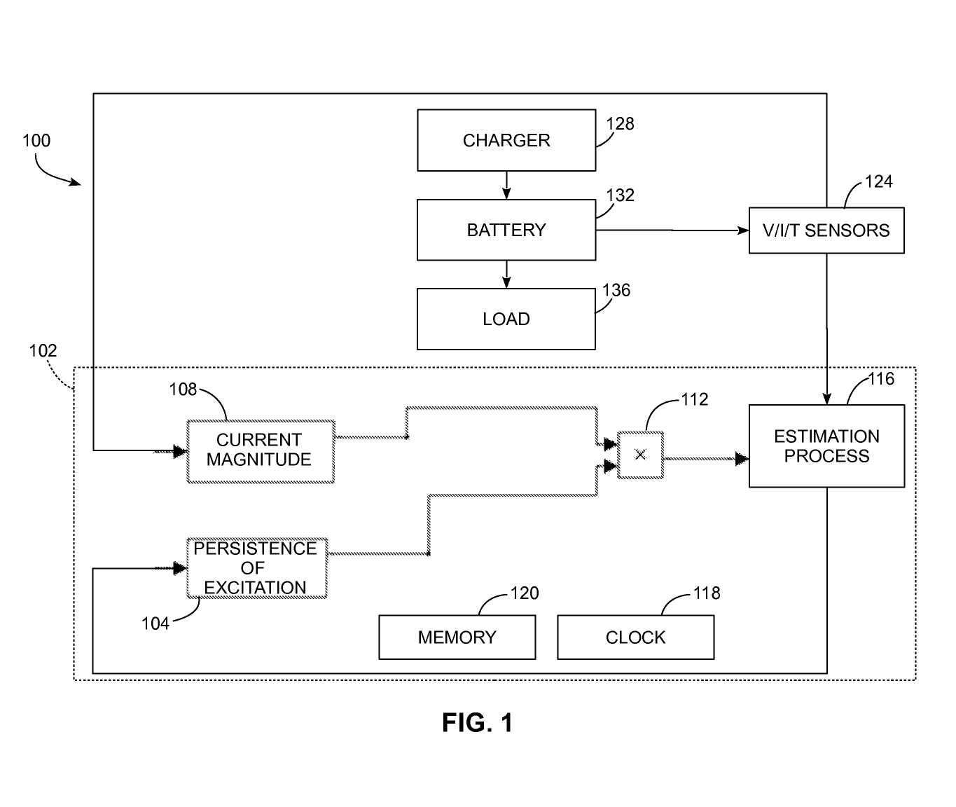

FIG. 1 depicts a battery monitoring system 100. The battery monitoring system 100 includes a controller 102 and one or more sensors 124. In FIG. 1, the sensors 124 include a voltage (V), current (I), and temperature (T) sensor. The sensors 124 are coupled to a battery 132 to monitor the voltage, the electrical input current that is supplied to the battery 132, the output current that flows from the battery 132 to the load 136, and temperature of the battery 132. Other embodiments include a different combination of sensors, or a single sensor such as a current sensor. In one configuration, the monitoring system 100, including the controller 102 and sensors 124, is integrated with the battery 132. In another configuration, the monitoring system 100 is a separate device that is detachably connected to the battery 132. In different configurations the battery 132 is a rechargeable or non-rechargeable battery, and the battery 132 in FIG. 1 represents either a single battery cell or a plurality of battery cells that are electrically connected in a battery pack. The battery 132 supplies electrical power to a load 136, with the load 136 drawing variable levels of electrical power from the battery 132 during operation. An optional charger 128 applies an electrical charging current to the battery 132 in configurations where the battery 132 is a rechargeable battery.

The controller 102 includes one or more processors, including microprocessors, microcontrollers, field programmable gate arrays (FPGAs), digital signal processors (DSPs), application specific integrated circuits (ASICs), and the like. In different embodiments, one or more components in the controller 102 and the sensors 124 are integrated into a single device in a system on a chip (SoC) configuration, or discrete components are electrically connected through a printed circuit board (PCB) or other suitable connection.

The controller 102 includes a memory 120. The memory 120 stores programmed instructions for processing data from the sensors 124, identifying a persistence of excitation in the battery 132, identifying a magnitude of electrical current flowing into the battery 132, and for performing an estimation process to estimate the state of the battery 132, including estimating at least one of the SOC, SOF, and SOH in the battery 132. The memory 120 also stores a history of previous estimates of the state of the battery 132. In the configuration of FIG. 1, the memory 120 includes a combination of volatile memory, such as static or dynamic random access memory (RAM), and a non-volatile memory, such as NAND or NOR flash memory or other suitable data storage device. Alternative embodiments can include different combinations of memory, including only volatile or only non-volatile memory devices.

The controller 102 also includes a clock generator 118. The clock generator 118 produces a repeating clock signal that provides a reference for operating synchronous logic components in the controller 102. As described in more detail below, the controller 102 monitors the operation of the battery 132 in discrete time intervals, and the controller 102 measures the time intervals with reference to a number of cycles of the clock signal received from the clock generator 118.

As depicted schematically in FIG. 1, the controller 102 implements hardware circuits, executes programmed instructions, or uses a combination of hardware and software to implement a persistence of excitation (PE) monitor 104, current magnitude monitor 108, and battery state estimation process 116 for the battery 132. The estimation process 116 receives sensor data from one or more of the voltage, current, and temperature sensors 124 to generate estimates of the state of the battery 132 using the sensor data and historic estimate data generated during past operation of the battery 132. The estimates are stored in the memory 120 and can be used for control of the battery 132 and for display using an output device such as an LCD output device (not shown).

The estimation process 116 includes a regressor vector, in which each regressor in the regressor vector is a predictor for a corresponding number of unknown parameters of the battery 132. The term “regressor vector” refers to an independent variable in a state and parameter estimation equation. Each regressor is alternatively referred to as a “predictor,” and the regressor is formed as a matrix with elements corresponding to the unknown parameters of the battery 132. For example, if the estimation process 116 generates estimates of three unknown battery model parameters P₀, P₁, and P₂, then each entry in the regressor vector includes a one-dimensional matrix of predictor terms x₀, x₁, and x₂ for each of the model parameters. The regressor vector can include matrices of predictor terms over a plurality of time periods extending into the past corresponding to predictors for the model parameters at earlier times. The estimation process 116 produces estimates for the present state of the battery 132 using both data from the sensors 124 and the previous state estimates for the battery 132. In addition to generating new estimates for the state of the battery 132, the estimation process 132 updates the predictor terms in the regressor vector as new measurements and data are received from the sensors 124. Thus, the regressor vector is updated with a new matrix of predictor values during each time period.

The estimation process 116 uses one or more numerical weighting values to discount the values of past estimates. For example, an exponential weighting function assigns greater weights to the most recent estimates and the weight values decrease exponentially for estimates that are farther in the past. The number of time periods in the past for which the estimates have a non-trivial contribution to the generation of the present estimate is referred to as the “effective window length.” In the estimation process 116, a weighting vector α includes weight values for previous time periods, and the effective window length is set by the number of non-trivial weight values in the weighting vector α.

The controller 102 enables the estimation process 116 only when both a persistence of excitation (PE) monitor 104 and electrical current magnitude monitor 108 indicate that the battery 132 is undergoing sufficient activity that enables the estimation process 116 to produce state estimates within an acceptable margin of error. In the controller 102, the PE monitor 104 and current magnitude monitor 108 both generate a binary output signal indicating whether the identified PE and magnitude of electrical current, respectively, of the battery 132 is sufficient to enable the estimation process 116 to proceed. For example, the outputs could be a “0” or a “1” and a multiplier 112 multiplies the outputs from the PE monitor 104 and current magnitude monitor 108 to generate an enable signal for the estimation process 116, and the estimation process 116 only proceeds with an enable signal of “1”.

The estimation process 116 is suspended when either or both of the PE monitor and current magnitude monitor 108 produce a “0” output. In the suspended state, the estimation process 116 retains the previous parameter estimates for the state of the battery, regressor vectors, and other internal state data. Thus, when the estimation process 116 resumes after being suspended, the intervening time period does not affect the estimated state of the battery 132. For example, if the estimation process 116 is enabled during time periods t₀-t₄, suspended during time periods t₅-t₈, and resumed during time period t₉, then the estimation process 116 proceeds as if the time period t₉ occurs immediately after t₄ and ignores the intervening time periods t₅-t₈.

In the controller 102, the PE monitor 104 identifies a persistence of an excitation value corresponding to the battery 132 using the regressor vector and weight values for the effective window length of the estimation process 116. The persistence of excitation (PE) matrix is a measure of how much information is contained in the regressors to robustly identify the unknown parameters in an equation. The persistence of excitation is defined as a positive semi-definite matrix, such as a real-valued 3×3 matrix variable R using the following equation: R(t)=∫₀^{t}e^{-α(6-τ)}φ(τ)φ(τ)^{τ}dτ where φ(τ) is the regressor vector at time τ in, φ(τ)^{τ} is a matrix transposition of the regressor, and the term e^{-α(6-τ)} is an exponential discounting function with the term α representing the reciprocal of the total time of the effective window length. The derivative of R with respect to time is \dot{R}(t)=−αR(t)+φ(t)φ(t)^{τ} where the state variable R is initialized as a zero-valued matrix at time 0 (R(0)=0_{3×3}).

The equations listed above describe the state variable R in a continuous time domain. In the monitoring system 100, however, the state variable R is updated at discrete time intervals during the operation of the battery 132 and the controller 102. The discrete-time update for R at time increment k follows the equation: R(k)=e^{-αT}^{ₛ}R(k−1)+1/α(1−e^{-αT}^{ₛ})φ(k)φ(k)^{T} where T_{S} is the length of a single sampling time period during which the regressor vector φ remains constant and state variable R is initialized to a zero matrix at time 0 (R(0)=0_{3×3}).

The state variable R is a matrix describing the persistence of excitation in the battery 132. To identify if the persistence of excitation in the battery 132 is sufficiently large to enable accurate state estimation with the estimation, the PE monitor 104 generates the scalar determinant value of the matrix R and compares the determinant value to a predetermined threshold scalar value. If the determinant of R exceeds the threshold value, then the PE monitor 104 outputs a logical “1”, and if the determinant of R is less than the threshold, then the PE monitor 104 outputs a logical “0” in the controller 102. In the monitoring system 100 the scalar threshold value is a predetermined value based on physical characteristics of the battery 132, or this value is calibrated during operation of the monitoring system 100.

In addition to the PE monitor 104, the controller 102 monitors the magnitude of an input electrical current to the battery with the current magnitude monitor 108. The current magnitude monitor 108 receives an input current level reading from the sensors 124 corresponding to the electrical current flowing into the battery 132. The input current can be received from the battery charger 128 during a recharging process if the battery 132 is a rechargeable battery, or the input current can be current returning to the battery 132 while driving the load 136 during a discharging process.

The current magnitude monitor 108 updates a state variable z based on the magnitude of current flowing into the battery 132. The derivative of the state variable z satisfies the following equation: ż(t)=−β(z−|u(t)|) where β is the reciprocal of a time constant of an internal current magnitude filter, and |u(t)| is the absolute value of the current that is applied to the battery at time t. The preceding equation applies to the derivative ż(t) when the state variable function z(t) is initialized to 0 at time 0 (z(0)=0). The preceding equation is a continuous time equation, in the controller 102, however, the state variable z is monitored in discrete time increments. The internal current magnitude filter is a low-pass filter that attenuates the effects of transient current spikes, such as the effects of rapid on/off switching, on the identified state of current flow into the battery 132. In one embodiment, the low-pass filter identifies an average input current over a predetermined time window prior to the time t that minimizes the effects of short-term current changes when identifying the average current into the batter 132.

In one embodiment of the controller 102, the state variable z is updated at discrete time increments instead of in a continuous manner. In a discrete time embodiment with time increments k, the controller 102 identifies the average current with the following the equation: z(k)=e^{-βT}^{ₛ}z(k−1)+(1−e^{-βT}^{ₛ})|u(k)| where Tₛ is the length of the sampling period for the time increment k and |u(k)| is the absolute value of the average current applied to the battery during the time increment k. The e^{-βT}^{ₛ} term is an exponential time discounting term applied to the value of the state variable z in the previous time increment z(k−1) for the low-pass filter.

After identifying the value of the state variable for time k, the current magnitude monitor compares the identified state variable value to a predetermined threshold for the current magnitude. If the state variable z exceeds the threshold, then the current magnitude monitor outputs a logical “1”, and if the state variable z is less than the threshold, then the current magnitude monitor outputs a logical “0” in the controller 102. In the monitoring system 100 the threshold value for the current magnitude is a predetermined value based on physical characteristics of the battery 132, or the value is calibrated during operation of the monitoring system 100.

As described above, the battery state estimation process 116 is enabled when both the PE monitor 104 and current magnitude monitor 108 generate the logical “1” output. In a parallel processing configuration, the excitation monitor 104, magnitude monitor 108, and battery state estimation process 116 operate concurrently. The battery state estimation process 116 continues during each time period for which the persistence of excitation exceeds the PE threshold and the input current magnitude exceeds the current magnitude threshold, and is suspended otherwise.

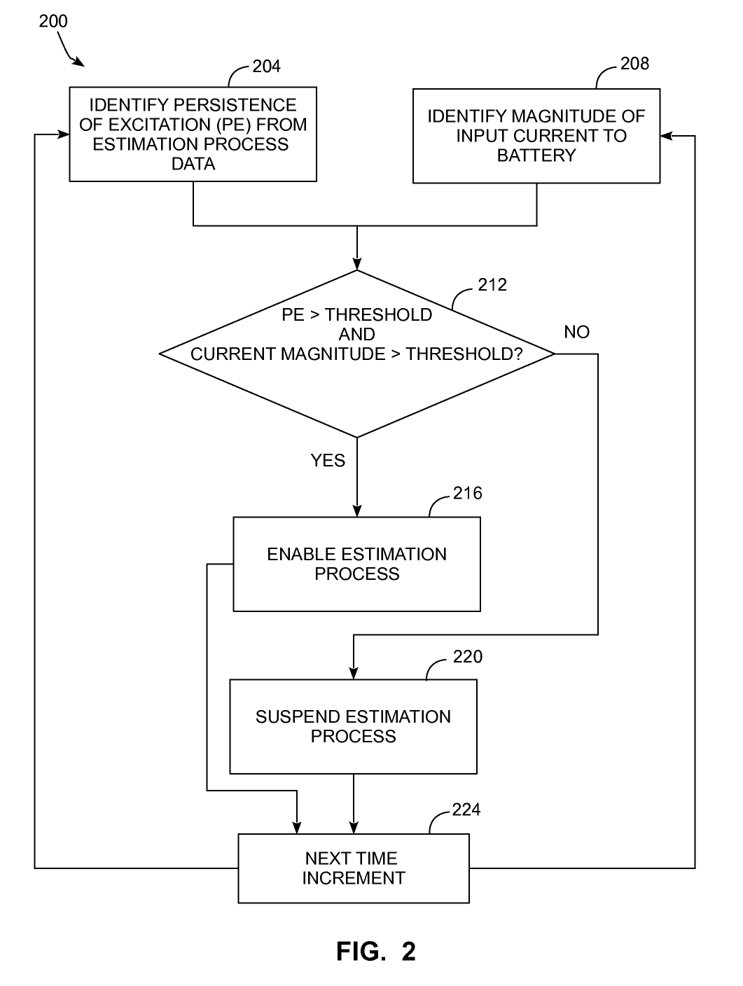

FIG. 2 depicts a process 200 for enabling and disabling a state estimation process for a battery. In the discussion below, a reference to the process 200 performing a function or action refers to a controller, such as controller 102, executing programmed instructions stored in a memory to operate one or more components in a printer to perform the function or action. Process 200 is described in conjunction with the battery monitoring system 100 for illustrative purposes.

Process 200 begins by identifying the persistence of excitation (PE) in the battery 132 (block 204) and identifying the magnitude of input current to the battery 132 (block 208). As described above with reference to the PE monitor 104, the PE is identified as a state variable corresponding to the regressor vector in the state estimation process 116. The current magnitude monitor 104 identifies the magnitude of input current as another state variable corresponding to the measured input current to the battery 132. In the example of FIG. 2, the processing described above with reference to blocks 204 and 208 occurs concurrently, but different embodiments can identify the PE and magnitude of input current serially in any order.

The process 200 continues by comparing the determinant of the identified PE state variable to the PE threshold and comparing the identified magnitude of the input current state variable to the current magnitude threshold (block 212). If both thresholds are exceeded, then the state estimation process for the battery 132 is enabled (block 216), but the state estimation process is suspended if either or both thresholds are not exceeded (block 220).

The enablement or suspension of the state estimation process lasts for one predetermined discrete increment during process 200. In the monitoring system 100, the controller 102 holds the outputs of the PE monitor 104 and the current magnitude monitor 108 for the length of a predetermined time increment. For example, each time increment lasts for a predetermined number of cycles of the clock generator 118. Process 200 continues during subsequent time increments (block 224) to dynamically enable and suspend the battery state estimation process with reference to changes in the PE and the magnitude of the input current that is supplied to the battery.

It will be appreciated that variants of the above-described and other features and functions, or alternatives thereof, may be desirably combined into many other different systems, applications or methods. Various presently unforeseen or unanticipated alternatives, modifications, variations or improvements may be subsequently made by those skilled in the art that are also intended to be encompassed by the following claims.

What is claimed:

1. A method of monitoring a battery comprising:
identifying, with a controller, a persistence of excitation in a battery;
identifying, with the controller, a magnitude of an electrical current that is supplied to the battery; and
performing, with the controller, a state estimation process for the battery only in response to the identified persistence of excitation exceeding a first predetermined threshold and the identified magnitude of the electrical current exceeding a second predetermined threshold.

2. The method of claim 1, the state estimation process being a state of charge estimation process.

3. The method of claim 1, the state estimation process being a state of health estimation process.

4. The method of claim 1, the state estimation process being a state of function estimation process.

5. The method of claim 1 further comprising:
performing, with the controller, the state estimation process during a first time period when the identified persistence of excitation exceeds the first predetermined threshold and the identified magnitude of the electrical current exceeds the second predetermined threshold to generate a first state estimate for the battery;
suspending, with the controller, the state estimation process during a second time period following the first time period when the identified persistence of excitation is below the first predetermined threshold or the identified magnitude of the electrical current is below the second predetermined threshold; and
resuming, with the controller, the state estimation process during a third time period following the second time period when the identified persistence of excitation exceeds the first predetermined threshold and the identified magnitude of the electrical current exceeds the second predetermined threshold, the state estimation process using the first state estimate for the battery as an initial state estimate at a beginning of the third time period.

6. The method of claim 1, the identification of the persistence of excitation further comprising:
identifying a state variable matrix of the persistence of excitation with reference to a regressor vector of the estimation process, and a plurality of weight values corresponding to previously generated estimates in the state estimation process; and
identifying the persistence of excitation as a determinant of the state variable matrix.

7. The method of claim 1, the identification of the magnitude of the electrical current further comprising:
identifying an average absolute value of the magnitude of the electrical current that is supplied to the battery during a predetermined time period.

8. The method of claim 7, the identification of the average absolute value of the magnitude of the electrical current further comprising:
identifying a plurality of absolute input current values during a plurality of time increments; and
applying a low-pass filter to the plurality of absolute input current values to identify the average absolute value of the magnitude of the electrical current during the plurality of time increments.

9. A system for monitoring a battery comprising:
a sensor configured to identify a level of electrical current that is supplied to the battery; and
a controller operatively connected to the sensor and configured to:
identify a persistence of excitation in a battery;
identify an average magnitude of the electrical current that is supplied to the battery with reference to at least one electrical current level identified by the sensor; and
perform a state estimation process for the battery only in response to the identified persistence of excitation exceeding a first predetermined threshold and the identified average magnitude of the electrical current exceeding a second predetermined threshold.

10. The system of claim 9 wherein the controller is configured to perform a state of charge estimation process only in response to the identified persistence of excitation exceeding the first predetermined threshold and the identified magnitude of the electrical current exceeding the second predetermined threshold.

11. The system of claim 9 wherein the controller is configured to perform a state of health estimation process only in response to the identified persistence of excitation exceeding the first predetermined threshold and the identified magnitude of the electrical current exceeding the second predetermined threshold.

12. The system of claim 9 wherein the controller is configured to perform a state of function estimation process only in response to the identified persistence of excitation exceeding the first predetermined threshold and the identified magnitude of the electrical current exceeding the second predetermined threshold.

13. The system of claim 9, the controller being further configured to:
perform the state estimation process during a first time period when the identified persistence of excitation exceeds the first predetermined threshold and the identified magnitude of the electrical current exceeds the second predetermined threshold to generate a first state estimate for the battery;
suspend the state estimation process during a second time period following the first time period when the identified persistence of excitation is below the first predetermined threshold or the identified magnitude of the electrical current is below the second predetermined threshold; and
resume the state estimation process during a third time period following the second time period when the identified persistence of excitation exceeds the first predetermined threshold and the identified magnitude of the electrical current exceeds the second predetermined threshold, the state estimation process using the first state estimate for the battery as an initial state estimate at a beginning of the third time period.

14. The system of claim 9, the controller being further configured to:
identify a state variable matrix of the persistence of excitation with reference to a regressor vector of the estimation process, and a plurality of weight values corresponding to previously generated estimates in the state estimation process; and
identify the persistence of excitation as a determinant of the state variable matrix.

15. The system of claim 9, the controller being further configured to:
identify an average absolute value of the magnitude of the electrical current that is supplied to the battery during a predetermined time period.

16. The system of claim 15, the controller being further configured to:
identifying a plurality of absolute input current values during a plurality of time increments; and
applying a low-pass filter to the plurality of absolute input current values to identify the average absolute value of the magnitude of the electrical current during the plurality of time increments.

17. The system of claim 9, the controller being further configured to:
identify the persistence of excitation with reference to at least one electrical current level identified by the sensor.

18. The system of claim 9 further comprising:
a temperature sensor configured to identify a temperature of the battery; and
the controller being operatively connected to the temperature sensor and further configured to:
identify the persistence of excitation with reference to at least one temperature identified by the temperature sensor.

19. The system of claim 9 further comprising:
a voltage sensor configured to identify an internal electrical voltage of the battery; and
the controller being operatively connected to the temperature sensor and further configured to:
identify the persistence of excitation with reference to at least one voltage identified by the voltage sensor.
